(19) United States
(12) Patent Application Publication
(10) Pub. No.: US 2002/0056839 A1
(43) Pub. Date: May 16, 2002

(54) Method of crystallizing a silicon thin film and semiconductor device fabricated thereby

(75) Inventors: Seung Ki Joo, Seoul (KR); Yeo Geon Yoon, Seoul (KR); Tae Kyung Kim, Seoul (KR)

Correspondence Address: Jay B. Johnson, Esq., Baker Botts L.L.P., Suite 600, 2001 Ross Avenue, Dallas, TX, 75201-2980, US

(73) Assignee: PT Plus Co. Ltd.

(21) Appl. No.: 09/855,431

(22) Filed: May 14, 2001

(30) Foreign Application Priority Data
Nov. 11, 2000 (KR) 2000-67005

(51) Int. Cl. H01L 29/04; H01L 31/0376

(52) U.S. Cl. 257/63; 257/64; 257/66; 438/482; 438/486; 438/149

(57) ABSTRACT

The present invention relates to a method of crystallizing an amorphous silicon thin film by thermal annealing the amorphous silicon thin film vapor deposited on a substrate in order to form a polycrystalline silicon thin film, and a semiconductor device fabricated by the method. According to the present invention, it is constructed such that a light-absorbing layer having absorbance of light much higher than that of the substrate or the amorphous silicon thin film is formed around the amorphous silicon thin film and is heated by a lamp when crystallizing the amorphous silicon thin film vapor deposited on the substrate by rapid annealing. Therefore, the temperature of the amorphous silicon thin film can be raised while restraining the increase in temperature of the substrate to the utmost. Accordingly, the amorphous silicon thin film can be crystallized without deformation of the substrate.

### BACKGROUND OF THE INVENTION

A thin film transistor, which is well known as a semiconductor device using a crystalline silicon thin film, may be fabricated by forming a thin film made of a semiconductor such as silicon onto a semiconductor substrate or an insulating substrate with an insulating layer formed thereon. Such a thin film transistor is used in various integrated circuits, and particularly, in a switching device formed at each pixel of a liquid crystal display or a driving circuit formed at a peripheral circuit portion.

In order to obtain a polycrystalline silicon thin film used in such a semiconductor device, it is well known that an amorphous silicon thin film vapor deposited onto a substrate should be thermal annealed at a temperature of about 600 C. or higher. Since the polycrystalline silicon thin film transistor as a device for driving a liquid crystal display should be formed on a transparent substrate such as a glass substrate, however, the thermal annealing temperature should be low temperature below about 600° C., i.e., below a deformation temperature of the glass substrate.

Therefore, studies for solving the problem have progressed in the following two directions.

First, there is a crystallization method in which a portion of the amorphous silicon thin film is fused and crystallized by irradiating laser thereon. According to this method, crystallization of the silicon thin film can be made without deformation of the substrate, since only a portion of the silicon thin film is heated without greatly raising the temperature of the substrate. However, there are problems such as non-uniformity of crystallization, high cost of production, decrease in yield, etc.

Second, there is a method, called a metal induced lateral crystallization, in which a crystallization temperature is lowered below about 500° C. by vapor depositing a metal thin film onto an amorphous silicon thin film. In this method, amorphous silicon is crystallized, by thermal annealing the amorphous silicon thin film in a furnace after vapor depositing the metal thin film onto the amorphous silicon thin film. According to the method, the problems such as non-uniformity of crystallization, high cost of production, and decrease in yield, which are problems produced in laser annealing, can be solved. However, there is still a problem in that thermal annealing should be made at temperature of about 500° C. during several hours if the method is to be applied to an actual process.

In order to solve the shortcomings, as a thermal annealing method, rapid thermal annealing has been proposed in which high temperature annealing is performed during a short period of time, at fast heating and cooling rate, using a lamp. In the rapid thermal annealing, the high temperature annealing can be performed without deformation of the substrate under the condition that the temperature of the amorphous silicon thin film is set different from that of the substrate, based on the fact that each material has different absorbance of light. However, it was difficult to further raise the temperature of the amorphous silicon thin film because absorbance of light of the amorphous silicon thin film is not highly greater.

### SUMMARY OF INVENTION

Therefore, it is an object of the present invention to solve these problems as mentioned above, more particularly, to provide a method of crystallizing an amorphous silicon thin film, wherein temperature of the amorphous silicon thin film can be sufficiently raised even by using rapid thermal annealing, and a semiconductor device fabricated by the method.

According to a first aspect of the present invention, there is provided a method of crystallizing a silicon thin film for forming an active layer of a thin film transistor, comprising the steps of preparing a substrate, forming on the substrate an amorphous silicon thin film and a light-absorbing layer made of material having absorbance of light higher than that of amorphous silicon, and heating the amorphous silicon thin film in order to crystallize the amorphous silicon and to form a crystalline silicon thin film by irradiating light onto and heating the amorphous silicon thin film.

According to a second aspect of the present invention, there is also provided a semiconductor device comprising a crystalline silicon thin film which is crystallized by irradiating light onto and heating a substrate and an amorphous silicon thin film formed on the substrate, and a light-absorbing layer made of material having absorbance of light higher than that of amorphous silicon and formed on the silicon thin film.

### BRIEF DESCRIPTION OF THE DRAWINGS

The embodiments of the present invention will be explained with reference to the accompanying drawings, in which:

FIG. 1 is a sectional view of a test piece used for comparison of rates of metal induced lateral crystallization by means of lamp line heating according to the present invention.

FIG. 2 is a graph illustrating the rates of the metal induced lateral crystallization upon rapid annealing of the test piece shown in FIG. 1.

FIGS. 3a to 3g are sectional views showing processes of fabricating a thin film transistor according to a first embodiment of the present invention.

FIGS. 4a to 4g are sectional views showing processes of fabricating a thin film transistor according to a second embodiment of the present invention.

FIGS. 5a to 5e are sectional views showing processes of fabricating a thin film transistor according to a third embodiment of the present invention.

FIGS. 6a to 6d are sectional views showing processes of fabricating a thin film transistor according to a fourth embodiment of the present invention.

FIGS. 7a to 7f are sectional views showing processes of fabricating a thin film transistor according to a fifth embodiment of the present invention.

FIGS. 8a to 8e are sectional views showing processes of fabricating a thin film transistor according to a sixth embodiment of the present invention.

FIGS. 9a to 9f are sectional views showing processes of fabricating a thin film transistor according to a seventh embodiment of the present invention.

### DETAILED DESCRIPTION OF THE INVENTION

Hereinafter, preferred embodiments according to the present invention will be explained in detail with reference to the accompanying drawings.

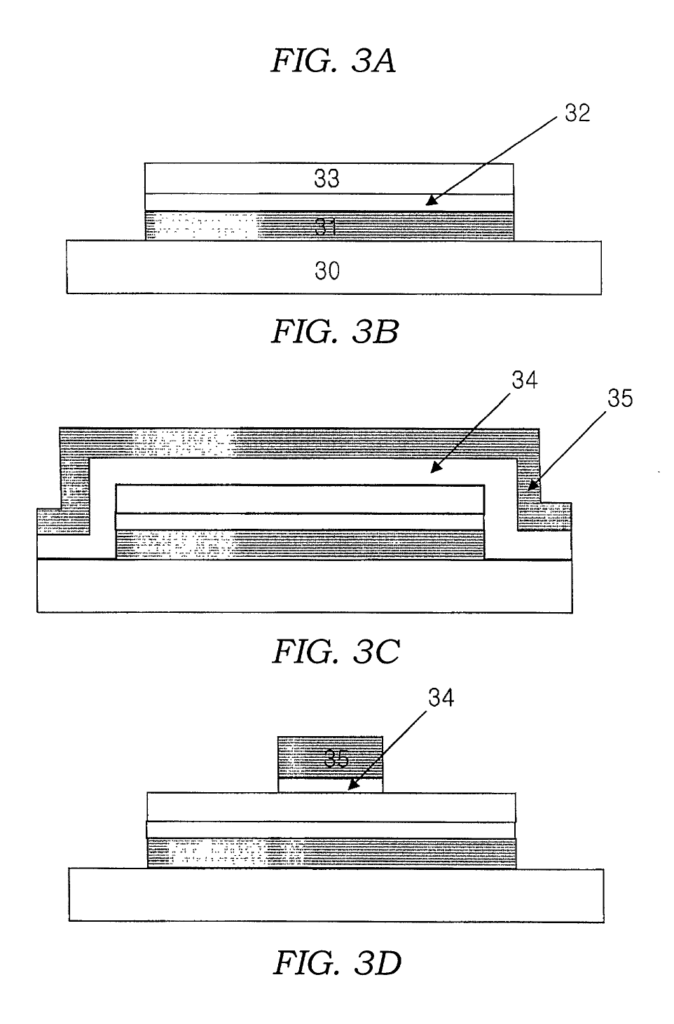

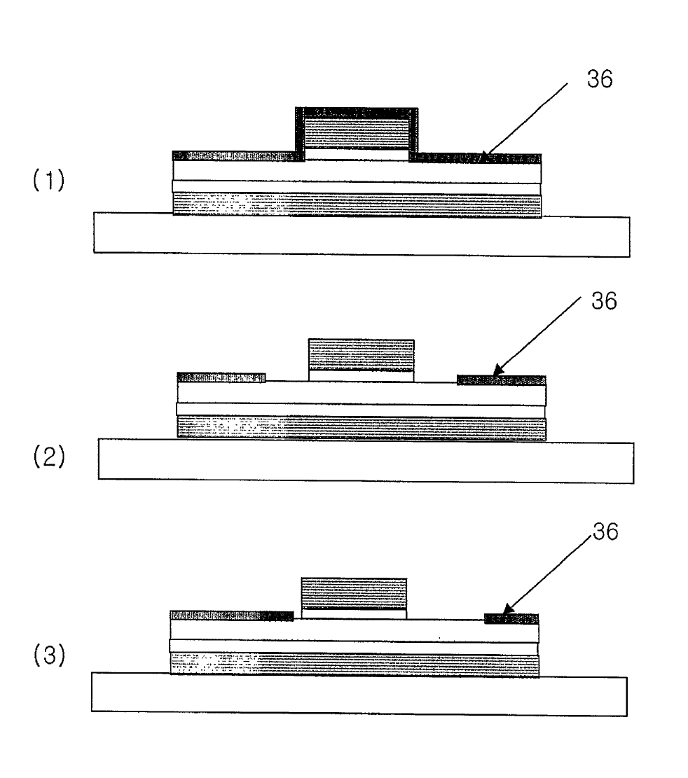

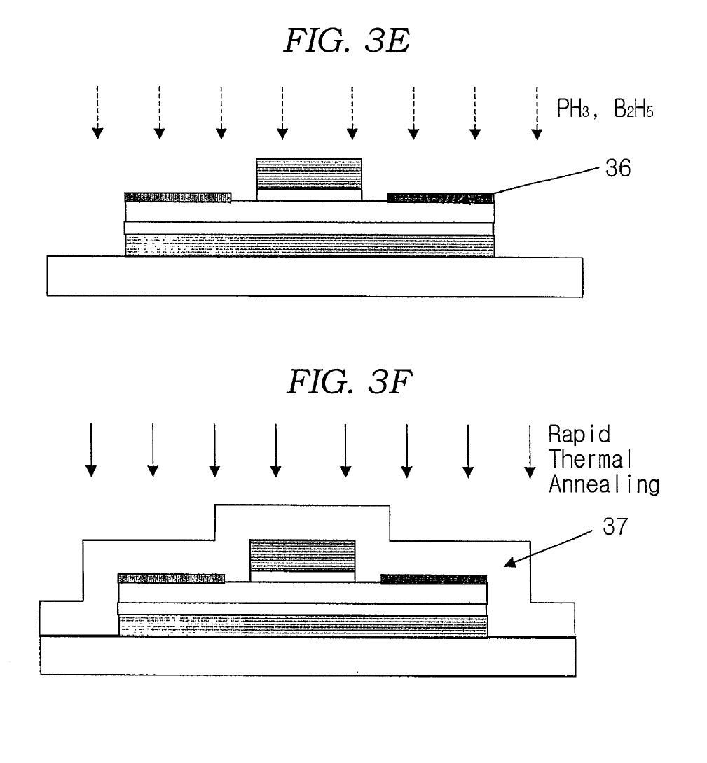

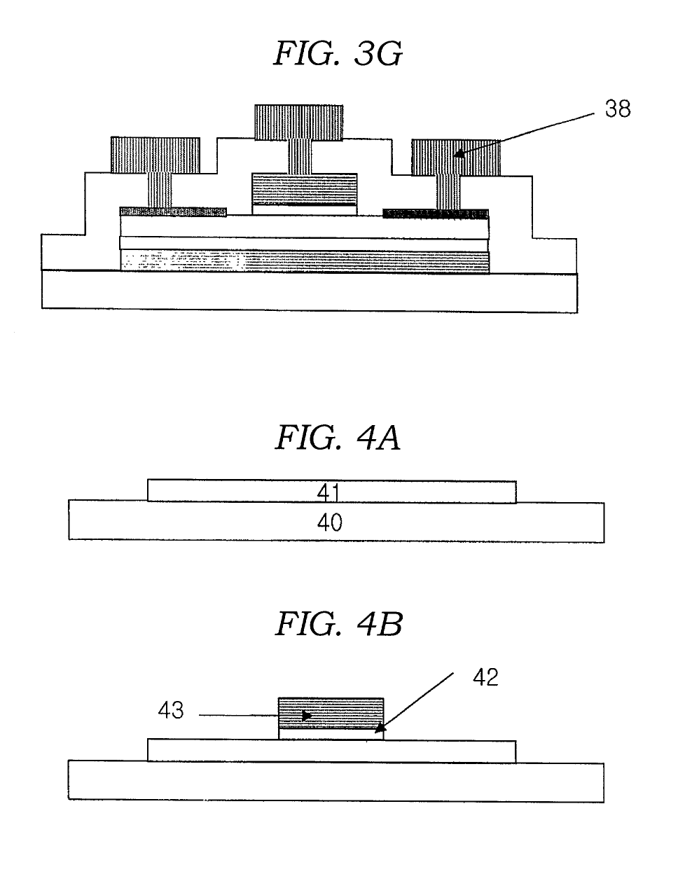

FIGS. 3a to 3g are sectional views showing processes of fabricating a thin film transistor according to a first embodiment of the present invention.

FIG. 3a is a sectional view showing a condition that a light-absorbing layer 31, a silicon oxide film 32 and an amorphous silicon layer 33 are formed and then patterned on a substrate 30.

The substrate 30 may be composed of a transparent insulating material such as Corning 1737 glass, quartz glass, silicon oxide or the like. Alternatively, a lower insulating layer (not shown) may be formed on the substrate 30. The lower insulating layer can be formed by performing vapor deposition of silicon oxide (SiO₂), silicon nitride (SiNₓ), silicon oxynitride (SiOₓN_{y}) or the composite material thereof at temperature of about 600° C. or lower and to thickness of 300 to 10,000 Å, more preferably 500 to 3,000 Å, using a vapor deposition method such as PECVD (plasma-enhanced chemical vapor deposition), LPCVD (low-pressure chemical vapor deposition), APCVD (atmospheric pressure chemical vapor deposition), ECR-CVD (Electron Cyclotron Resonance CVD), etc.

The light-absorbing layer 31 is formed by vapor depositing a material having high absorbance of light onto the substrate 30 using a coating technique such as sputtering, evaporation, CVD, electroplating, etc. For example, the light-absorbing layer 31 can be formed by vapor depositing a molybdenum (Mo) thin film having thickness of about 3,000 Å onto the substrate 30 using Magnetron sputtering. Degree of crystallization of the amorphous silicon can be varied depending on whether or not the light-absorbing layer 31 is vapor deposited, the position and the thickness of the layer 31, etc.

The silicon oxide film 32 can be vapor deposited in the same manner as the lower insulating layer mentioned above, and can be served as an insulating layer between the light-absorbing layer 31 and the amorphous silicon layer 33.

The amorphous silicon layer 33 can be formed by performing vapor deposition of amorphous silicon to thickness of 100 to 3,000 Å, more preferably 500 to 1,000 Å, using PECVD, LPCVD or sputtering. The amorphous silicon layer 33 is constructed to be an active layer of the thin film transistor; and it can comprise a source region, a drain region, a channel region, and an additional device/electrode region to be formed later.

The triple layer (i.e., the light-absorbing layer 31, the silicon oxide film 32 and the amorphous silicon layer 33) formed on the substrate 30 can be patterned in a desired shape. At this time, by simultaneously etching both the light-absorbing layer 31 and the silicon oxide film 32 together with the amorphous silicon layer 33, the light-absorbing layer 31 can be locally formed only at a portion needed for heating. Alternatively, the light-absorbing layer 31 may not be etched in case of a frontlight liquid crystal display. Herein, the shape or size of the pattern can be changed, and the size or shape of the light-absorbing layer can be variously changed.

FIG. 3b is a sectional view of a structure that a gate insulating layer 34 and a gate electrode 35 are vapor deposited onto the substrate 30 and the patterned triple layer 31 to 33. The gate insulating layer 34 can be formed by performing vapor deposition of silicon oxide (SiO₂), silicon nitride (SiNₓ), silicon oxynitride (SiOₓN_{y}) or the composite material thereof to thickness of 300 to 3,000 Å, more preferably 500 to 1,000 Å, using a vapor deposition method such as PECVD, LPCVD, APCVD, and ECR-CVD. The gate electrode 35 can be formed by vapor depositing conductive material such as metal material, doped polysilicon or the like onto the gate insulating layer 34 to thickness of 1,000 to 8,000 Å, more preferably 2,000 to 4,000 Å, using the method such as sputtering, evaporation, PECVD, LPCVD, APCVD, and ECR-CVD.

Next, as shown in FIG. 3c, the gate insulating layer 34 and the gate electrode are etched in their desired shapes.

FIG. 3d is a sectional view showing a configuration where a thin film 36 made of metal such nickel, etc. is further coated for the purpose of low-temperature crystallization. The metal thin film 36 having thickness of several Å may either be formed at a whole surface thereof (FIG. 3d (1)) so as not to need additional patterning or be offset from the gate insulating layer 34 and the gate electrode 35 (FIG. 3d (2)). In a case where the offset is employed, both a case where the offset from the source region is identical to that from the drain region (FIG. 3d (2)) and a case where the offset from the source region is different from that from the drain region (FIG. 3d (3)) can be used.

FIG. 3e is a view showing a process of doping source and drain regions of the active layer by using the gate electrode as a mask. For example, in a case where N-MOS TFT is manufactured, dopants such as PH₃, P, As, etc. are doped at a dose of about 1.0×10¹¹ to 1.0×10²²/cm³ ( preferably, 1.0×10¹⁵ to 1.0×10²¹/cm³) with energy of about 10 to 200 KeV (preferably, 30 to 100 KeV) using ion shower doping or ion implantation. Further, in a case where P-MOS TFT is manufactured, dopants such as B₂H₆, B, BH₃, etc. are doped at a dose of about 1.0×10¹¹ to 1.0×10²²/cm³ (preferably, 1.0×10¹⁴ to 1.0×10²¹/cm³) with energy of about 20 to 70 KeV. It is apparent that several times of doping processes using additional masks are required in a case where a junction portion having a weakly doped region or an offset region is formed in the drain region or where CMOS is formed.

FIG. 3f is a sectional view showing a process of rapid thermal annealing of a covering film 37 after forming the film 37 as an insulating layer. At the time of rapid thermal annealing, light from a lamp may be irradiated in an upward direction, a downward direction, and both upward and downward directions. It is preferable that the light irradiated at this time has a wavelength of 400 nm or more. As a method for irradiating the light, a scanning method in which linear light scans can be used. The opaque amorphous silicon layer 33 with the metal thin film 36 for low-temperature crystallization being vapor deposited thereon is heated by the light irradiated as such, whereas the transparent substrate 30 is not heated by the light. Furthermore, the irradiated light is absorbed by the light-absorbing layer 31 located below the amorphous silicon layer 33, and the light absorbed into the light-absorbing layer 31 causes the amorphous silicon layer 33 to be further heated. It will be more specifically explained below. In case of the light having a wavelength falling within the range of the visible light, the substrate 30 made of transparent material such as glass, etc. can scarcely absorb light energy, whereas the amorphous silicon layer 33 absorbs a little amount of the light energy. Further, the light-absorbing layer 31 made of metal, etc. absorbs the light energy greatly well. Thus, progress rate of crystallization of the amorphous silicon layer 33 can be more enhanced as thermal annealing rate for the amorphous silicon layer 33 can be improved by means of the energy provided by the light-absorbing layer 31.

Then, as shown in FIG. 3g, the thin film transistor according to the first embodiment of the present invention can be accomplished by forming metal lines 38 for voltage application after removing a portion of the covering film 37.

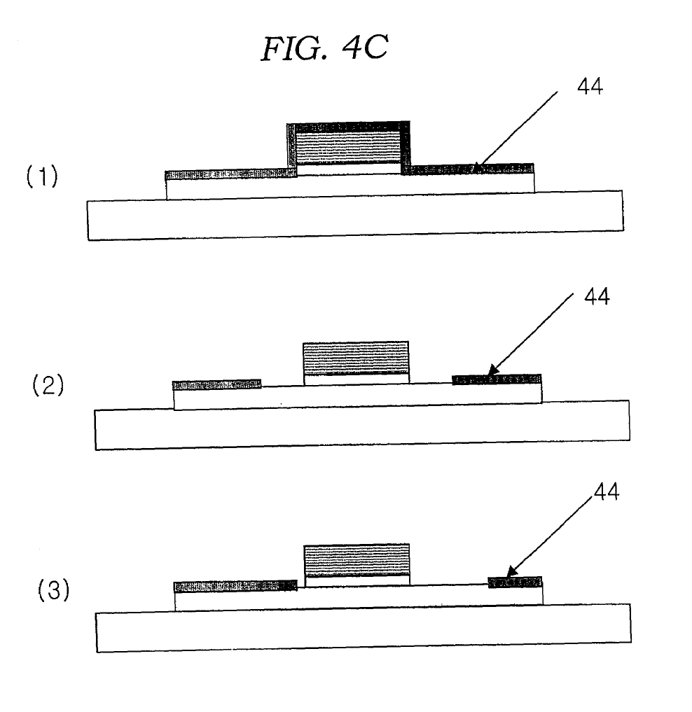

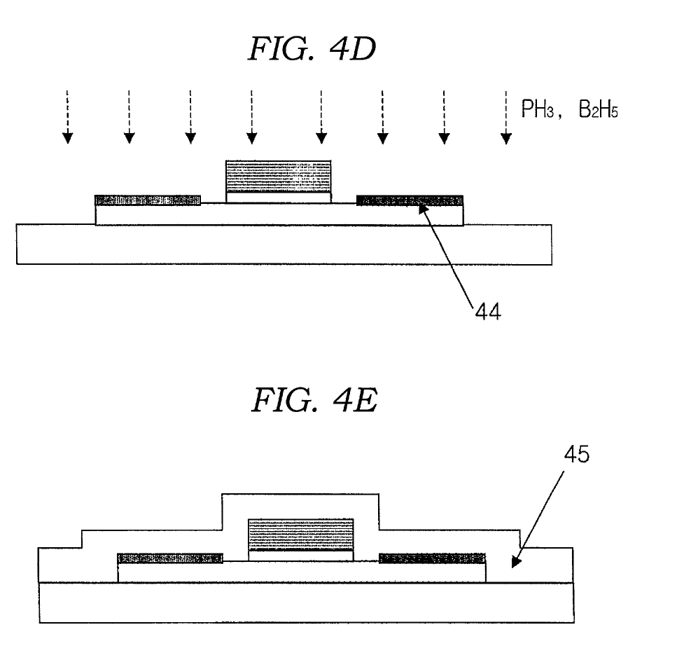

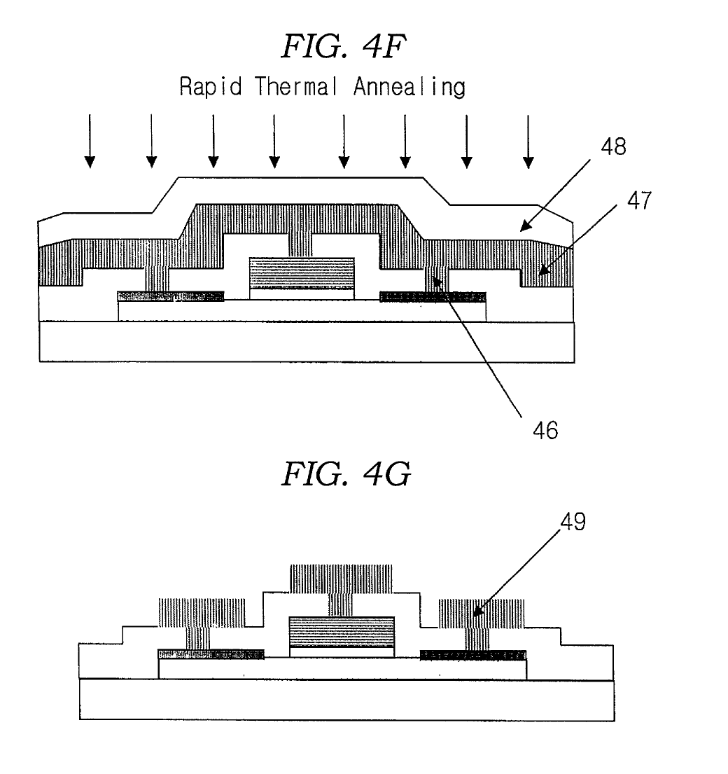

Next, referring to FIGS. 4a to 4g, processes of fabricating a thin film transistor according to a second embodiment of the present invention will be described.

FIG. 4a is a sectional view showing a condition where an amorphous silicon layer 41 serving as an active layer of the thin film transistor is formed and patterned onto a substrate 40. A lower insulating layer (not shown) may be alternatively formed on the substrate 40 in the same way as the first embodiment.

The amorphous silicon layer 41 can be formed by vapor depositing amorphous silicon to thickness of 100 to 3,000 Å, more preferably 500 to 1,000 Å using PECVD, LPCVD, and sputtering and then by patterning it in a desired shape. The active layer formed by the amorphous silicon layer 41 may comprise a source region, a drain region, a channel region, and an additional device/electrode region to be formed later.

Next, as shown in FIG. 4b, a gate insulating layer 42 and a gate electrode 43 are vapor deposited onto the substrate 40 and the patterned amorphous silicon layer 41, and then they are etched in a desired shape.

FIG. 4c is a sectional view showing a configuration where a thin film 44 made of metal such as nickel is coated for the purpose of low-temperature crystallization. The metal thin film 44 having thickness of several Å0 may either be formed at a whole surface thereof (FIG. 4c (1)) so as not to need additional patterning or be offset from the gate electrode 43 (FIG. 4c (2)). In a case where the offset is employed, both a case where the offset from the source region is identical to that from the drain region (FIG. 4c (2)) and a case where the offset from the source region is different from that from the drain region (FIG. 4c (3)) can be used.

Next, as shown in FIG. 4d, the gate electrode 43 is used as a mask, and thus, the source and drain regions of the active layer are doped.

Then, as shown in FIG. 4e, a first covering film 45 serving as an insulating layer is further deposited.

FIG. 4f is a sectional view showing a process for rapid thermal annealing after the first covering layer 45 is etched to form a contact hole 46 and they are vapor deposited by a light-absorbing layer 47 which is in turn covered with a second covering film 48. At this time, the light-absorbing layer 47 is made of wiring metal that is capable of forming metal lines 49 for subsequent voltage application. Even in this case, light from a lamp may be irradiated in an upward direction, a downward direction and both two directions in the same way as the first embodiment. Further, the opaque amorphous silicon layer 41 with the metal thin film 44 for low-temperature crystallization being vapor deposited thereon is heated by the light irradiated as such, whereas the transparent substrate 40 is not heated by the light. Furthermore, the irradiated light is absorbed by the light-absorbing layer 47 located above the amorphous silicon layer 41, and the light absorbed into the light-absorbing layer 47 causes the amorphous silicon layer 41 to be further heated. Thus, progress rate of crystallization of the amorphous silicon layer 41 can be more enhanced as the thermal annealing rate for the amorphous silicon layer 41 can be increased.

Then, as shown in FIG. 4g, the thin film transistor according to the second embodiment of the present invention can be accomplished by patterning the light-absorbing layer 47 and forming the metal lines 49 for the voltage application to the transistor after removing the second covering film 48 located over the layer 47.

In this embodiment, the process of FIG. 4c may be omitted if the metal such as nickel for low-temperature crystallization is used in the light-absorbing layer of FIG. 4f.

In the first and second embodiments as described above, it is illustrated that the crystallization of the amorphous silicon in the channel region is produced by a metal induced lateral crystallization in which the silicon is crystallized toward a side of a portion abutting on the metal thin film. However, crystallization of the silicon can be carried out by the methods other than the metal induced lateral crystallization, for example, metal induced crystallization (MIC) or solid phase crystallization (SPC).

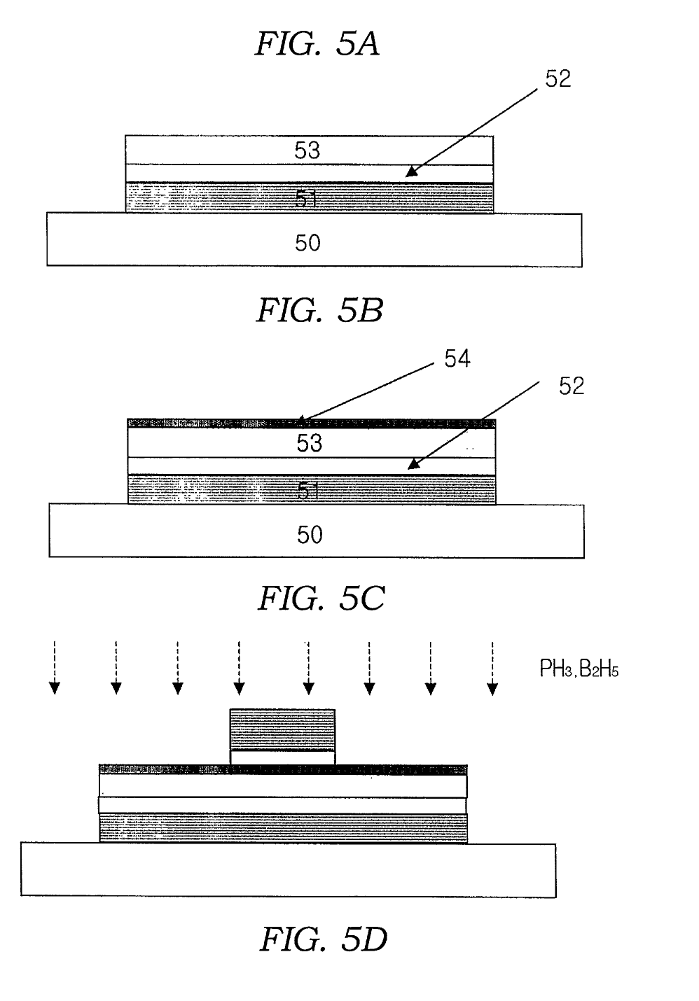

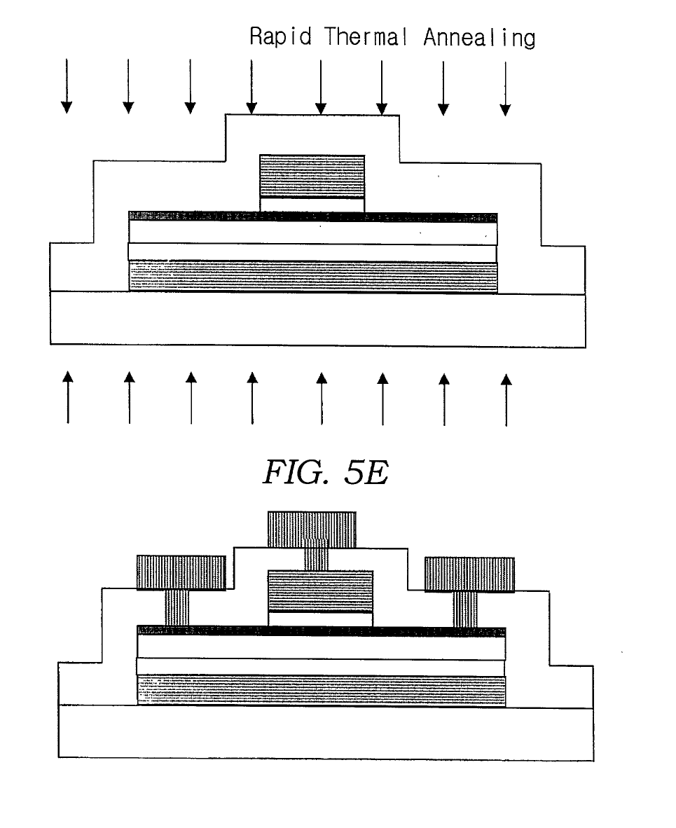

FIGS. 5a to 5e are section views showing processes of fabricating a thin film transistor according to a third embodiment of the present invention and illustrate an example of crystallization using the metal induced crystallization. As shown, after a light-absorbing layer 51, an insulating layer 52 and an amorphous silicon layer 53 are vapor deposited and patterned onto a substrate 50 (FIG. 5a), nickel is vapor deposited thereon or injected thereinto, or an organic solvent containing the nickel is coated thereon (FIG. 5b). And then, after a gate insulating layer and a gate electrode are formed thereon, dopants such PH₃, B₂H₆, etc. are doped onto source and drain regions of an active layer by using the gate electrode as a mask (FIG. 5c). Subsequently, crystallization is advanced by rapid thermal annealing (FIG. 5d). At this time, in the embodiment employing the metal induced crystallization, amorphous silicon abutting on a thin film 54 made of metal such as nickel is crystallized. Finally, a thin film transistor according to the third embodiment of the present invention can be completed by forming metal lines for voltage application to the transistor (FIG. 5e).

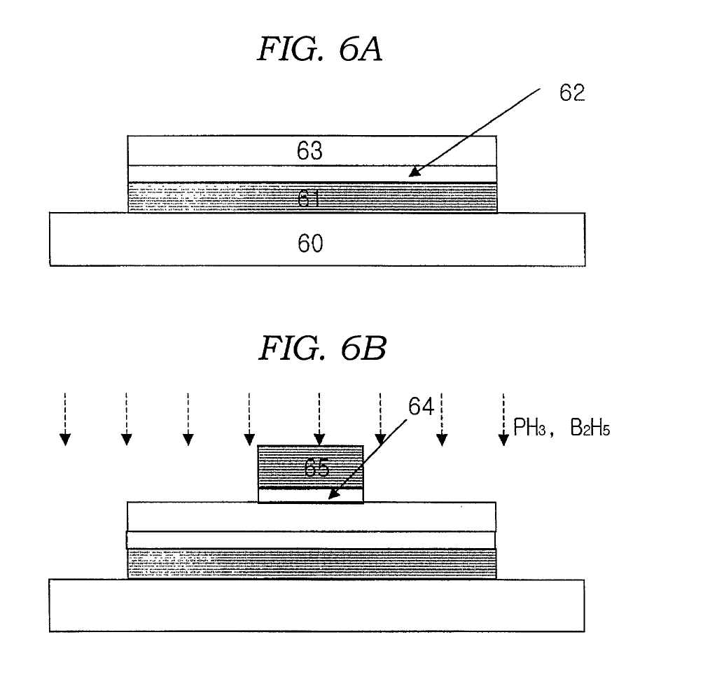

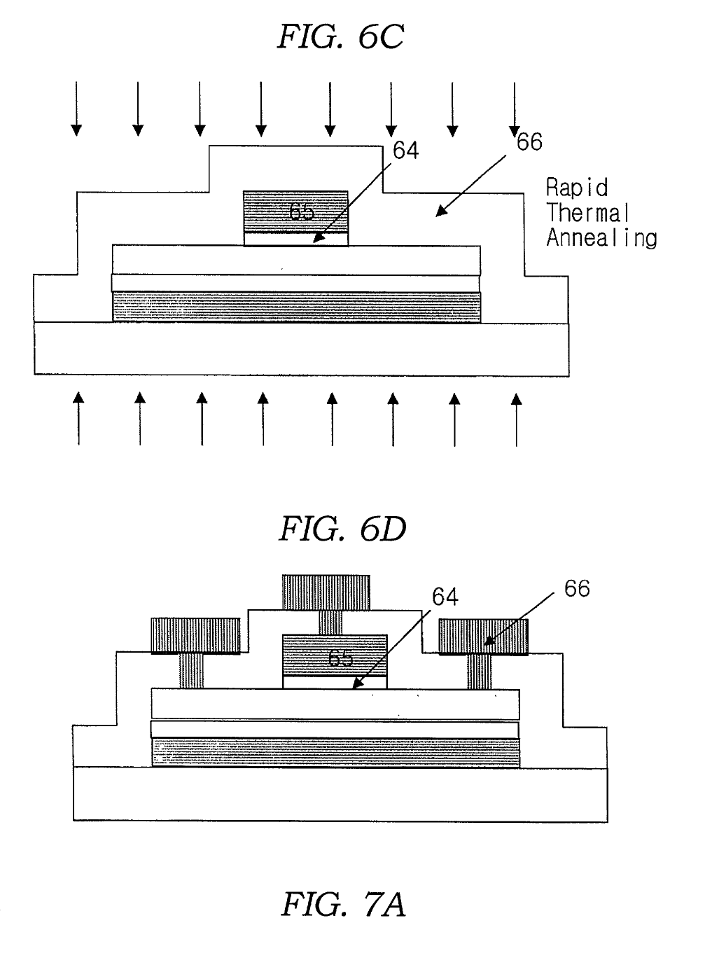

FIGS. 6a to 6d are sectional views showing processes for fabricating a thin film transistor according to a fourth embodiment of the present invention, and illustrate an example of crystallization using the solid phase crystallization. As shown, after a light-absorbing layer 61, an insulating layer 62 and an amorphous silicon layer 63 are vapor deposited and patterned onto a substrate 60 (FIG. 6a), a gate insulating layer and a gate electrode are formed thereon and dopants such PH₃, B₂H₆, etc. are doped onto source and drain regions of an active layer by using the gate electrode as a mask (FIG. 6b). And then, crystallization is advanced by rapid thermal annealing (FIG. 6c). As described above, in the embodiment employing the solid phase crystallization, the crystallization is advanced without vapor depositing a thin film made of metal such as nickel. Finally, a thin film transistor according to the fourth embodiment of the present invention can be accomplished by forming metal lines for voltage application to the transistor (FIG. 6d).

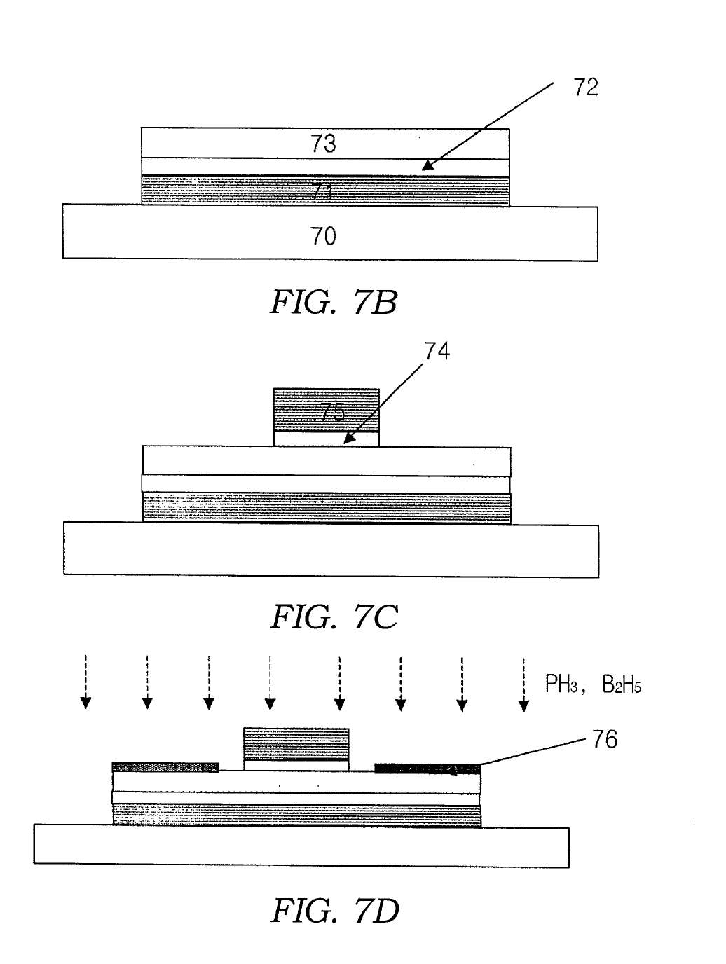

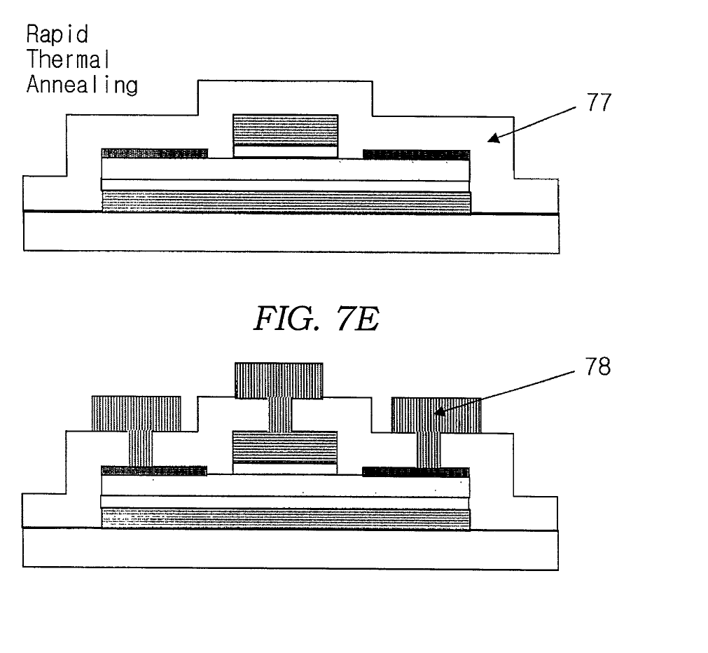

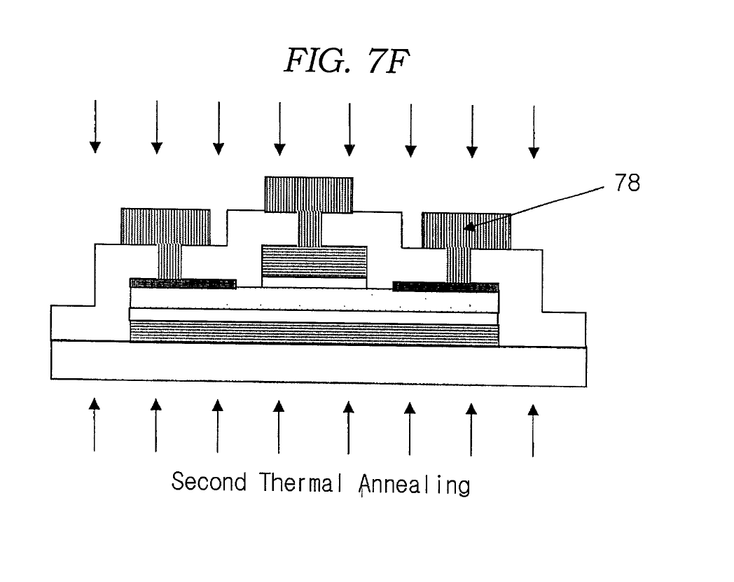

FIGS. 7a to 7f are sectional views showing processes for fabricating a thin film transistor according to a fifth embodiment of the present invention, and illustrate an example using additional thermal annealing. As shown, after a light-absorbing layer 71, an insulating layer 72 and an amorphous silicon layer 73 are vapor deposited and patterned onto a substrate 70 (FIG. 7a), a gate insulating layer and a gate electrode are formed thereon (FIG. 7b). And then, a thin film 76 made of metal such as nickel, etc. is coated thereon for low-temperature crystallization. Further, the metal thin film 76 is offset from the gate insulating layer and the gate electrode, and then, dopants such PH₃, B₂H₆, etc. are doped onto source and drain regions of an active layer by using the gate electrode as a mask (FIG. 7c). Furthermore, a covering film 77 is applied onto a whole surface thereof, and then, crystallization is advanced by first thermal annealing using a furnace or rapid thermal annealing (FIG. 7d).

Subsequently, metal lines 78 for voltage application to the transistor are formed (FIG. 7e). Finally, a thin film transistor according to the fifth embodiment of the present invention can be completed by causing the resulting structure to be subjected to second thermal annealing using rapid thermal annealing (FIG. 7f). When additional thermal annealing is performed, degree of crystallization of the amorphous silicon can be further improved.

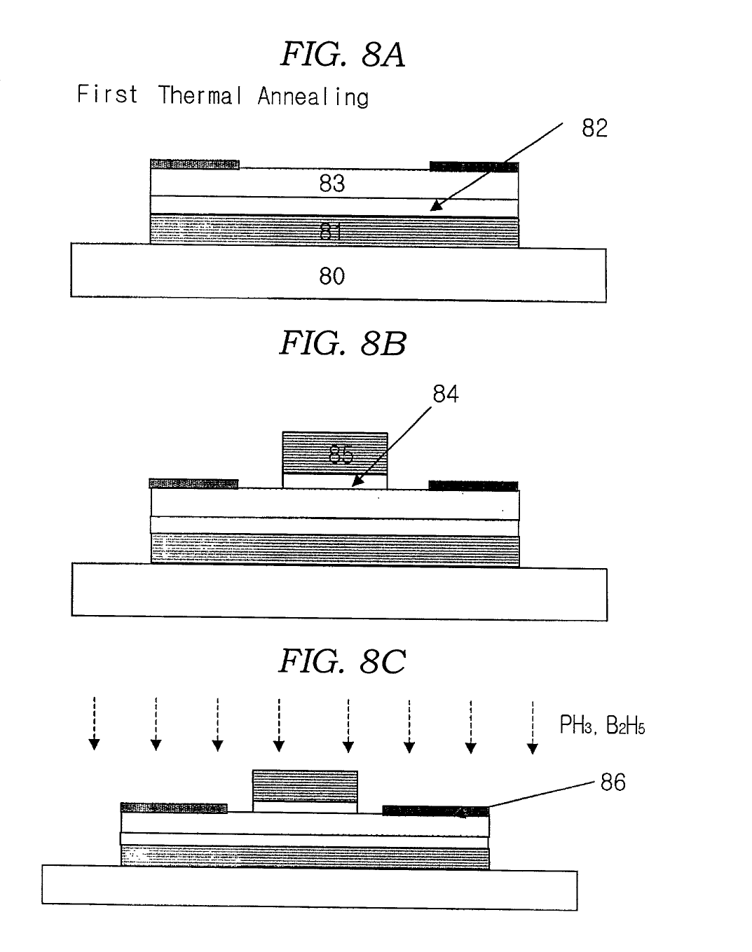

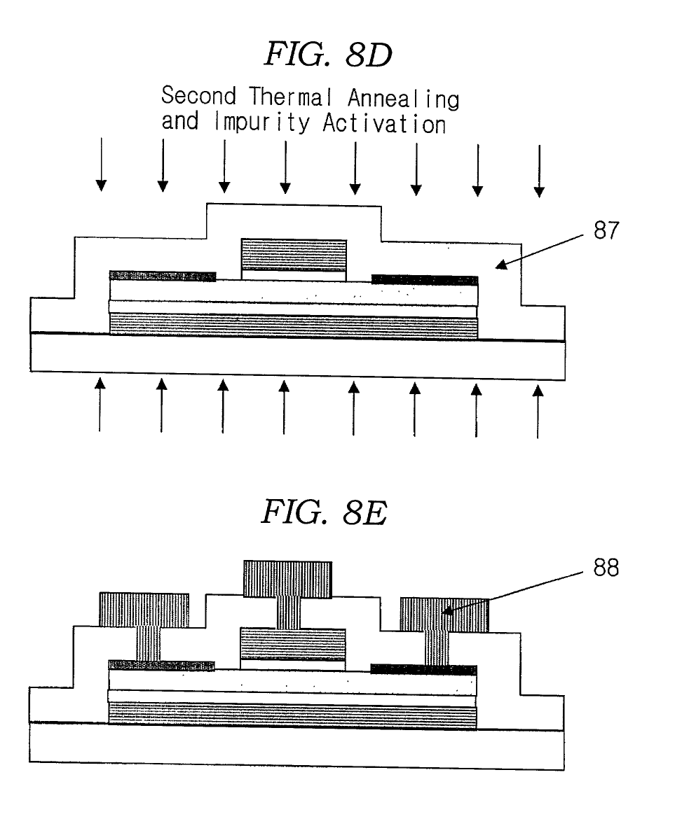

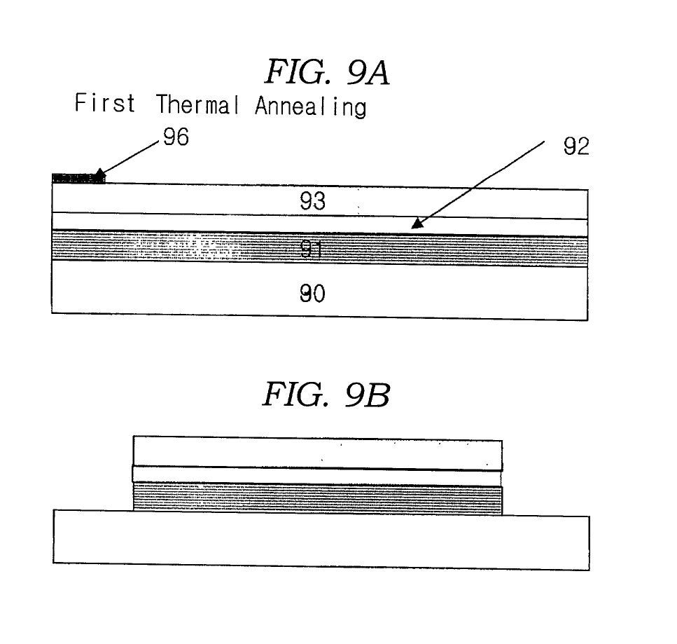

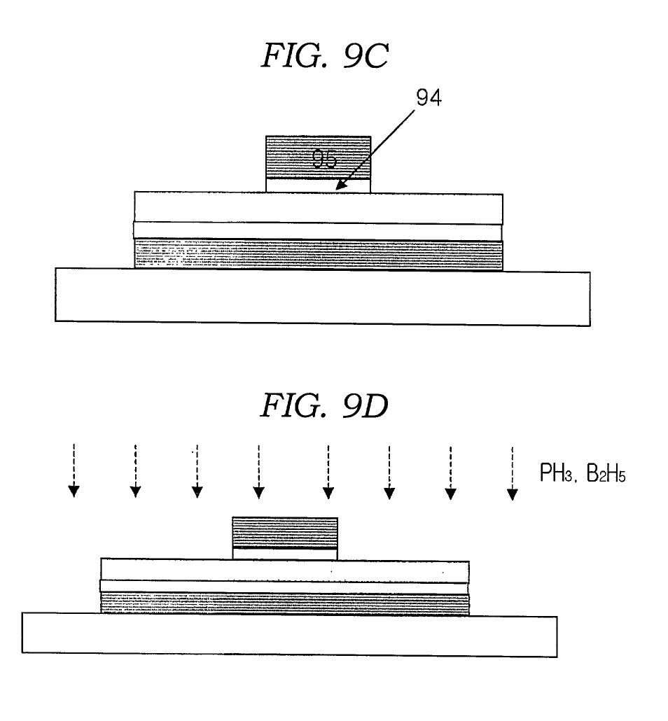

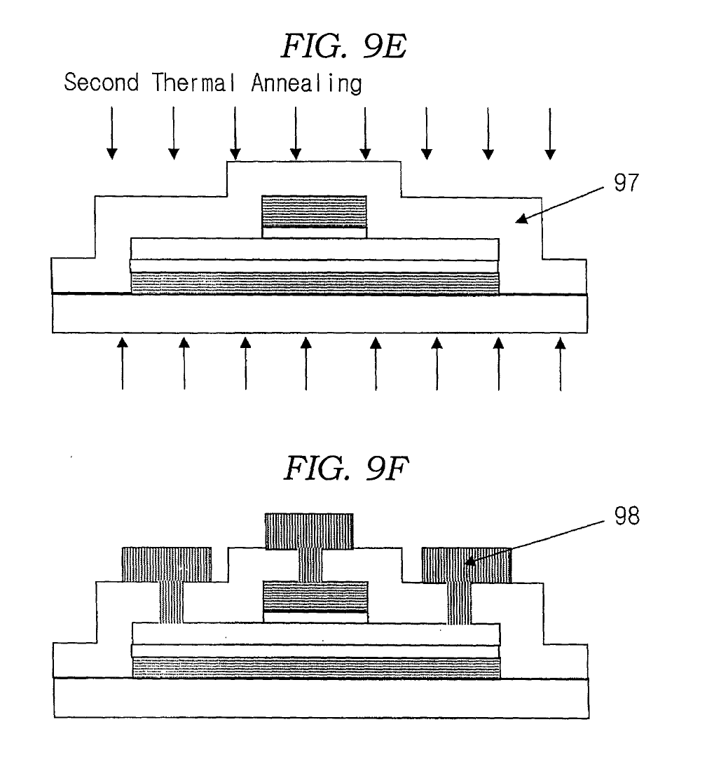

In the embodiments described above, since thermal annealing is performed after impurities are doped, both crystallization of the amorphous silicon and activation of the impurities can be achieved during thermal annealing thereof. However, as shown in FIGS. 8 and 9, thermal annealing may be performed before the impurities are doped.

FIGS. 8a to 8e are section views showing processes for fabricating a thin film transistor according to a sixth embodiment of the present invention. As shown, after a light-absorbing layer 81, an insulating layer 82, an amorphous silicon layer 83 and an offset metal thin film 86 for low-temperature crystallization are first coated onto a substrate 80, first thermal annealing is performed and crystallization is advanced (FIG. 8a). And then, a gate insulating layer 84 and a gate electrode 85 are formed thereon (FIG. 8b), and dopants such PH₃, B₂H₆, etc. are doped onto source and drain regions of an active layer by using the gate electrode as a mask (FIG. 8c). Subsequently, after a covering film 87 is applied onto a whole surface thereof, crystallization is promoted together with activation of the impurities by means of second thermal annealing using the rapid thermal annealing (FIG. 8d). Finally, a thin film transistor according to the sixth embodiment of the present invention can be completed by forming metal lines 88 for voltage application to the transistor (FIG. 8e).

FIGS. 9a to 9f are section views showing processes for fabricating a thin film transistor according to a seventh embodiment of the present invention. As shown, after a light-absorbing layer 91, an insulating layer 92, an amorphous silicon layer 93 and a partly formed metal thin film 96 for low-temperature crystallization are first coated onto a substrate 90, first thermal annealing is performed and crystallization is advanced (FIG. 9a). And then, a region of an active layer is patterned (FIG. 9b). Thereafter, a gate insulating layer 94 and a gate electrode 95 are formed thereon (FIG. 9c), and dopants such PH₃, B₂H₆, etc. are doped onto source and drain regions of an active layer by using the gate electrode as a mask (FIG. 9d). Subsequently, after a covering film 97 is applied onto a whole surface thereof, crystallization is promoted together with activation of the impurities by means of second thermal annealing using the rapid thermal annealing (FIG. 9e). Finally, a thin film transistor according to the seventh embodiment of the present invention can be completed by forming metal lines 98 for voltage application to the transistor (FIG. 9f). Therefore, it can be understood from the embodiment that the thermal annealing may be performed before the active layer region is patterned, as shown in FIG. 9a.

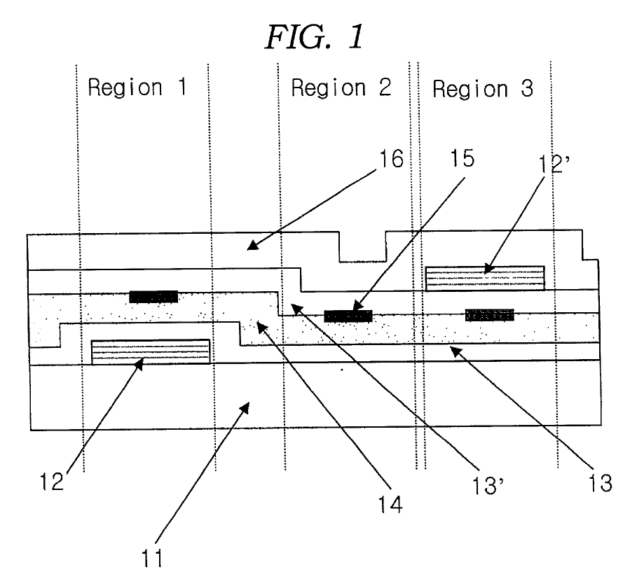

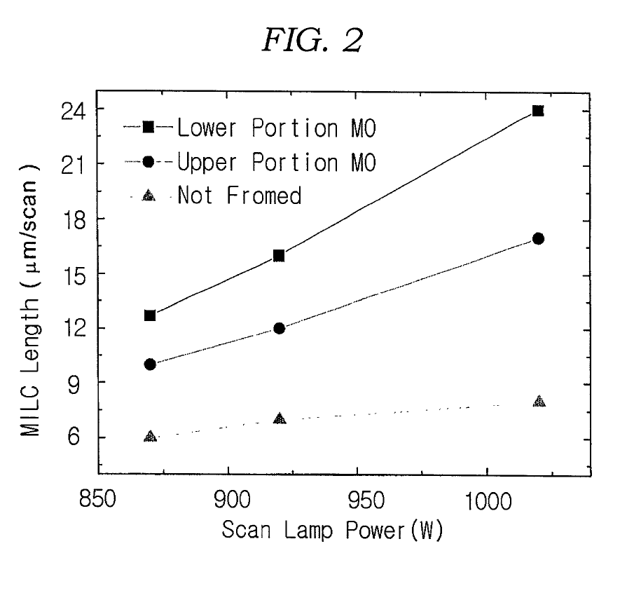

Next, referring to FIGS. 1 and 2, a description of rates of metal induced lateral crystallization depending on positions of light-absorbing layers will be made.

FIG. 1 is a sectional view of a test piece used for comparison of the rates of metal induced lateral crystallization by means of lamp line heating according to the present invention. As shown, the test piece is composed of three different parts (regions 1 to 3). The region 1 is a part where a light-absorbing layer for optical absorption is vapor deposited onto a position below amorphous silicon; the region 2 is a part where a light-absorbing layer is not formed; and the region 3 is a part where a light-absorbing layer is vapor deposited onto a position above amorphous silicon. For example, the test piece constructed as such can be manufactured as follows:

First, after a molybdenum (Mo) thin film having thickness of 3,000 Å is vapor deposited onto a substrate 11 using Magnetron sputtering, a lower light-absorbing layer 12 for optical absorption is formed through a photographic etching process. Then, after a silicon oxide film 13 for insulation between the lower light-absorbing layer 12 and an amorphous silicon layer 14 is vapor deposited onto a whole surface using ECR-CVD, the amorphous silicon layer 14 is vapor deposited using PECVD.

Thereafter, a metal thin film 15 made of nickel and having thickness of 20 Å is partly formed for the purpose of metal induced lateral crystallization. Further, an upper light-absorbing layer 12′ made of molybdenum and having thickness of 3,000 Å is partly formed in the same manner as the lower light-absorbing layer 12, after a silicon oxide film 13′0 for insulation between the amorphous silicon layer 14 and the upper light-absorbing layer 12′ to be vapor deposited above is formed as shown in FIG. 1. Furthermore, in order to prevent oxidation of the test piece during its thermal annealing and to enhance efficiency of thermal annealing, a silicon oxide film 16 is vapor deposited as a covering layer. The test piece manufactured as such is sectionalized into the regions 1 to 3, and relative rates of the metal induced lateral crystallization can be compared with each other by thermal annealing the regions at the same time and by performing metal induced lateral crystallization of the regions.

FIG. 2 is a graph illustrating the rates of the metal induced lateral crystallization upon rapid annealing of the test piece shown in FIG. 1. As shown, it can be understood that even at identical lamp power, the rate of crystallization of the case where the light-absorbing layer is vapor deposited onto an upper or lower portion of the amorphous silicon layer (regions 1 and 3) is much faster than that of the case where the light-absorbing layer is not formed (region 2). Further, it can be confirmed that the rate of crystallization of the case where the light-absorbing layer is vapor deposited onto the lower portion of the amorphous silicon layer (region 1) is faster than that of the case where the light-absorbing layer is vapor deposited onto the upper portion thereof (region 3). The test piece was thermal annealed while maintaining nitrogen atmosphere at 500° C. during 10 hours. As a result, the rates of crystallization of the three regions were identical to each other. It can be understood from the result that during rapid thermal annealing thereof, increases of crystallization rates of regions 1 and 3 arose from the fact that the amorphous silicon in the regions 1 and 3 was heated to higher temperature as compared with the region 2 during the thermal annealing, rather than from changes of thermal stresses in the thin film.

As described above, by vapor depositing the light-absorbing layer around the object to be heated in case of rapid thermal annealing characterized by heating by the light, temperature of a semitransparent thin film made of material such as amorphous silicon can be selectively raised in the region where the light-absorbing layer exists, and thus, rate of thermal annealing can be improved. In such a case, the thermal annealing rate can be further increased in a case where the light-absorbing layer is vapor deposited onto the lower portion as compared with a case where the light-absorbing layer is vapor deposited onto the upper portion.

According to the present invention, the amorphous silicon thin film can be selectively thermal annealed at high temperature and can be rapidly crystallized without damage of the substrate. Further, uniformity and manufacturing yield of the crystalline silicon thin film can be improved at a relatively low cost of production. Furthermore, the crystalline silicon thin film having crystallinity different from each other at respective portions of the substrate can be obtained, because only one thermal annealing, depending on the presence, relative position and thickness of the vapor deposited light-absorbing layer, can provide various portions of the substrate with different thermal annealing effects. Owing to the above advantage, a desired device can be fabricated by only one thermal annealing, even in a case where the various devices having different characteristics, such as switching devices formed at the pixels of the liquid crystal display, driving circuits formed at peripheral circuit portions or the like, are put together on the substrate.

Although the present invention has been described with respect to the preferred embodiments thereof, the present invention is not limited to the embodiments and various modifications and changes based on the technical features of the present invention may fall within the scope of the invention. For example, although it is described in the second embodiment of the present invention that the light-absorbing layer 47 is formed to be also used as the wiring metal, it is apparent that the light-absorbing layer can be formed such that it can also be used as the other components such as the gate electrode.

Therefore, it should be understood that a person having an ordinary skill in the art to which the present invention pertains can make various modifications and changes to the present invention without departing from the spirit and scope of the invention defined by the appended claims.

What is claimed is:

1. A method of crystallizing a silicon thin film for forming an active layer of a thin film transistor, comprising the steps of:
preparing a substrate;
forming an amorphous silicon thin film and a light-absorbing layer on said substrate, said light-absorbing layer being made of material having absorbance of light higher than that of amorphous silicon; and
heating said amorphous silicon thin film in order to crystallize said amorphous silicon and to form a crystalline silicon thin film by irradiating light onto said amorphous silicon thin film.

2. The method as claimed in claim 1, further comprising a step of vapor depositing a metal thin film for lowering crystallization temperature of said amorphous silicon onto at least a portion of said amorphous silicon thin film prior to said heating step.

3. The method as claimed in claim 2, further comprising a step of forming a gate electrode onto said amorphous silicon thin film prior to said vapor deposition step of said metal thin film, wherein said metal thin film is vapor deposited onto whole surfaces of said amorphous silicon thin film and said gate electrode.

4. The method as claimed in claim 2, further comprising a step of forming a gate electrode onto said amorphous silicon thin film prior to said vapor deposition step of said metal thin film, wherein said metal thin film is formed to be spaced apart from said gate electrode by a predetermined distance.

5. The method as claimed in claim 4, wherein said predetermined distance is set such that the distances from a source and a drain formed below said gate electrode are different from each other.

6. The method as claimed in claim 1, wherein said material having higher absorbance of light comprises metal.

7. The method as claimed in claim 6, wherein said metal is molybdenum.

8. The method as claimed in claim 1, wherein said light-absorbing layer is formed on an upper portion, a lower portion or both portions of said amorphous silicon thin film.

9. The method as claimed in claim 8, further comprising a step of removing a portion formed on said upper portion of said amorphous silicon thin film among said light-absorbing layer formed on said amorphous silicon thin film after said heating step.

10. The method as claimed in claim 8, wherein crystallization conditions of said amorphous silicon thin film are changed depending on material, position and thickness of said light-absorbing layer.

11. The method as claimed in claim 1, further comprising a step of forming wiring for electric connection by patterning said light-absorbing layer.

12. The method as claimed in claim 1, further comprising steps of forming a gate insulating layer before forming said light-absorbing layer and of forming said gate electrode by patterning said light-absorbing layer.

13. The method as claimed in claim 1, further comprising an additional heating step of improving crystallinity of said amorphous silicon by repeatedly performing said heating step.

14. The method as claimed in claim 1, further comprising a step of thermal annealing and preliminarily crystallizing said amorphous silicon prior to said heating step.

15. The method as claimed in claim 1, wherein impurities are activated during said heating step which is performed after said impurities has been doped onto said amorphous silicon thin film.

16. The method as claimed in claim 1, wherein said light is irradiated by a lamp.

17. The method as claimed in claim 1, wherein said light is irradiated in an upward direction, a downward direction or both upward and downward directions of said substrate.

18. The method as claimed in claim 1, wherein an insulating layer is interposed between said amorphous silicon thin film and said light-absorbing layer and said insulating layer is made as one of a silicon oxide film, a silicon nitride film, a silicon oxynitride film and a composite film thereof.

19. The method as claimed in claim 1, wherein wavelength of said light is 400 nm or more.

20. The method as claimed in claim 1, wherein said light is irradiated onto said silicon thin film as a whole and at a time.

21. The method as claimed in claim 1, said heating step is performed by scanning of linear light.

22. A semiconductor device, comprising:
a crystalline silicon thin film which is crystallized by irradiating light onto and heating a substrate and an amorphous silicon thin film formed on said substrate, and
a light-absorbing layer made of material having absorbance of light higher than that of amorphous silicon and formed on said silicon thin film.

23. The semiconductor device as claimed in claim 22, wherein a metal thin film for lowering crystallization temperature of said amorphous silicon is formed on at least a portion of said silicon thin film.

24. The semiconductor device as claimed in claim 23, wherein a gate electrode is formed on said silicon thin film, and wherein said metal thin film is vapor deposited onto whole surfaces of said silicon thin film and said gate electrode.

25. The semiconductor device as claimed in claim 23, wherein a gate electrode is formed on said silicon thin film, and wherein said metal thin film is formed to be spaced apart from said gate electrode by a predetermined distance.

26. The semiconductor device as claimed in claim 25, wherein said predetermined distance is set such that the distances from a source and a drain formed below said gate electrode are different from each other.

27. The semiconductor device as claimed in claim 22, wherein said material having higher absorbance of light comprises metal.

28. The semiconductor device as claimed in claim 27, wherein said metal is molybdenum.

29. The semiconductor device as claimed in claim 22, wherein said light-absorbing layer is formed on an upper portion, a lower portion or both portions of said silicon thin film.

30. The semiconductor device as claimed in claim 22, wherein wiring for electric connection is formed by patterning said light-absorbing layer.

31. The semiconductor device as claimed in claim 22, wherein a gate electrode is formed by patterning said light-absorbing layer.

32. The semiconductor device as claimed in claim 22, wherein an insulating layer is interposed between said silicon thin film and said light-absorbing layer, and wherein said insulating layer is made as one of a silicon oxide film, a silicon nitride film, a silicon oxynitride film and a composite film thereof.

33. The semiconductor device as claimed in claim 29, wherein said light-absorbing layer formed on said upper portion of said silicon thin film among said light-absorbing layer formed on said silicon thin film is removed.
